(19) United States
(12) Patent Application Publication
(10) Pub. No.: US 2009/0267590 A1
(43) Pub. Date: Oct. 29, 2009

(54) METHOD OF ENABLING TRIGGERING AN OSCILLOSCOPE

(75) Inventors: Emmanuel Atta, Rochester, MN (US); Paul Rudrud, Rochester, MN (US)

Correspondence Address: CANTOR COLBURN LLP - IBM ROCHESTER DIVISION, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/111,353

(22) Filed: Apr. 29, 2008

(51) Int. Cl. G01R 1/067

(52) U.S. Cl. 324/149

(57) ABSTRACT

A method of enabling triggering an oscilloscope includes placing a tip portion of a probe, electrically connected to the oscilloscope, on an electrical circuit, applying pressure to the probe tip, and establishing an electrical contact inside the probe as a result of pressure applied to the probe tip. The electrical contact closes an electrical circuit that triggers the oscilloscope.

### BACKGROUND OF THE INVENTION

1. Field of the Invention

This invention relates to the art of electrical testing equipment and, more particularly, to a method of enabling triggering an oscilloscope.

2. Description of Background

An oscilloscope is a type of electronic test equipment that allows signal voltages to be viewed, usually as a two-dimensional graph or trace of one or more electrical potential differences (vertical axis) plotted as a function of time or of some other voltage (horizontal axis). Conventionally, a probe(s) is connected to portions of an electrical circuit. Once a good contact is established, a trigger is activated to capture a signal that is represented on the oscilloscope as the two-dimensional trace. Once the signal is captured, the trigger is de-activated and the probe(s) removed from the portion of the electrical circuit. Activating the trigger before the probes are applied or after the probes are removed can result in acquiring signal noise that may have an adverse effect on the signal being studied.

Often times two technicians are required to properly capture a signal, particularly when two handheld probes are required. When using two handheld probes to capture a signal, one technician connects the oscilloscope to the circuit, and another technician activates the trigger. In this manner, a good contact is established before the signal is captures thereby eliminating noise. In addition, signals can be quickly captured from multiple circuits or portions of circuits. However, a drawback exists in that at least two technicians are required to perform a test. In order to proved more flexibility, particularly for simple testing, one oscilloscope probe includes a handle mounted trigger enable. The handle mounted trigger enable activates a light that aids the technician in viewing the circuit and triggers a computer based oscilloscope. In this manner, a technician can probe and trigger at the same time. However, as noted above, activating the light to see the circuit and enabling triggering before a good contact is established can lead to unacceptable signal noise. Moreover, the handle mounted trigger enable requires that the technician possess enough fingers to both grip the probe and activate the trigger enable. Individuals missing fingers could not operate the handle mounted trigger enable.

### SUMMARY OF THE INVENTION

The shortcomings of the prior art are overcome and additional advantages are provided through the provision of a method of enabling triggering an oscilloscope. The method includes placing run and stop switches in a tip portion of a probe, electrically connected to the oscilloscope,, applying pressure to the probe tip, and closing and opening the run and stop switches as a result of pressure applied to the probe tip. The run and stop switches enable and disable triggering the oscilloscope.

Additional features and advantages are realized through the techniques of exemplary embodiments of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates an electrical test system including an oscilloscope having test probes constructed in accordance with an exemplary embodiment of the invention;

FIG. 2 illustrates a test probe constructed in accordance with an exemplary embodiment of the invention in a non-enabled configuration and connected to an electrical circuit;

FIG. 3 illustrates the test probe shifting from the non-enabled configuration of FIG. 2 to a enabled configuration as a result of an application of pressure; and

FIG. 4 illustrates the test probe shifting back from the enabled configuration of FIG. 3 to a non-enabled configuration as a result of the application of pressure being removed while maintaining contact with the electrical circuit.

The detailed description explains the exemplary embodiments of the invention, together with advantages and features, by way of example with reference to the drawings.

### DETAILED DESCRIPTION OF THE INVENTION

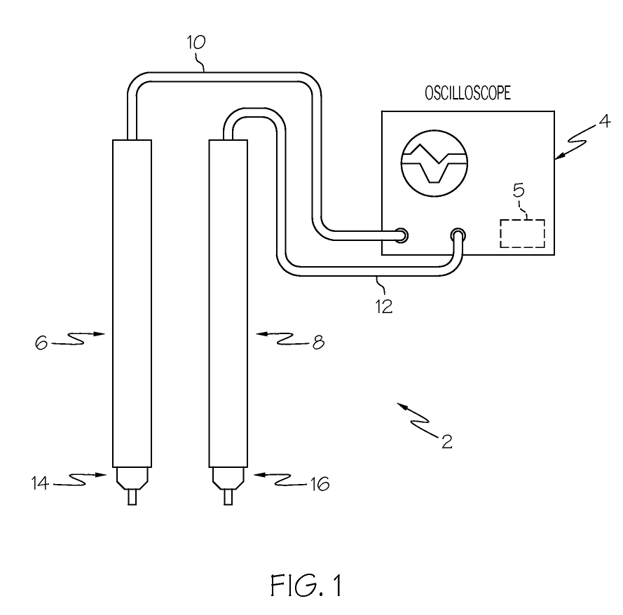

With initial reference to FIG. 1, an electrical test system constructed in accordance with exemplary embodiments of the present invention is indicated generally at 2. Test system 2 includes an oscilloscope 4 having first and second test probes 6 and 8. Test probes 6 and 8 are electrically connected to oscilloscope 4 through respective leads 10 and 12. As will become more fully evident below, each test probe 6 and 8 includes a retractable probe tip 14 and 16 respectively. At this point it should be understood that as each test probe is constructed similarly, a detailed description will follow with respect to test probe 6 with an understanding that test probe 8 includes identical structure.

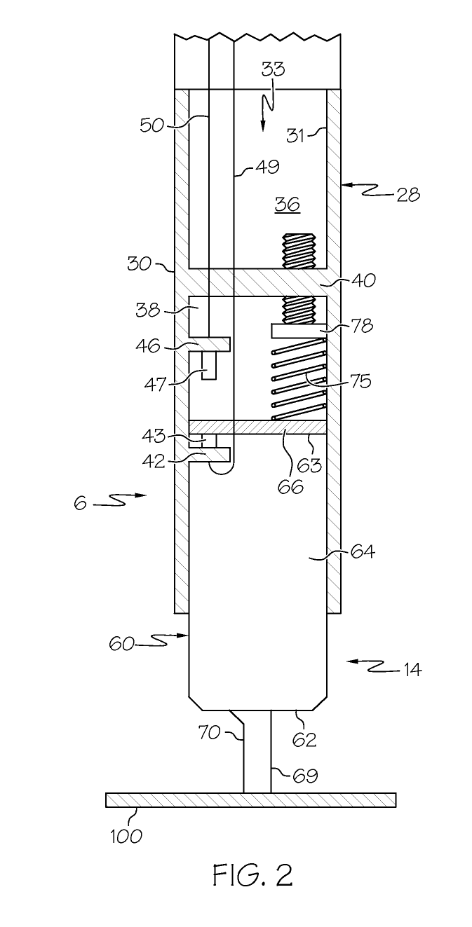

As best shown in FIG. 2, test probe 6 includes a main body portion 28 having an outer wall 30 and an inner wall 31 that define an interior chamber 33. Interior chamber 33 is further divided into a first interior chamber portion 36 and a second interior chamber portion 38 by a wall member 40. Main body portion 28 includes a first contact support 42 extending from inner wall 31. First contact support 42 includes a first or stop contact 43. Main body portion 28 also includes a second contact support 46 that extends from inner wall 31. Second contact support 46 is spaced from first contact support 42 and includes a second or run contact 47. Each contact 43, 47 is electrically coupled to oscilloscope 4 via corresponding leads 49 and 50. Leads 49 and 50 form part of lead 10 connecting test probe 6 to oscilloscope 4.

Retractable probe tip 14 is received within second interior chamber portion 38 and includes a main body 60 having a first end 62 that extends to a second end 63 through an intermediate portion 64. As will be discussed more fully below, a contact plate 66 is positioned at second end 63. Probe portion 69 includes a tip portion 70 that extends through intermediate portion 64. Retractable probe tip 14 is biased out from second interior chamber portion 38 by a force applied by a spring 75. Spring 75 extends between wall member 40 and contact plate 66. In accordance with one aspect of the exemplary embodiment, tension in spring 75 is adjusted by a tension adjust mechanism provided at wall member 40.

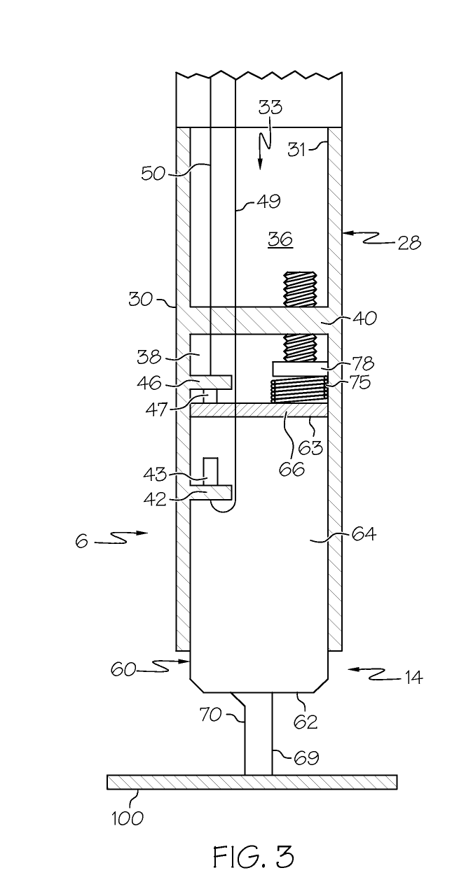

Having described an exemplary construction of test probe 6, reference will now be made to FIGS. 2-4 in describing a method of triggering oscilloscope 4 via test probe 6. Of course it should be understood that oscilloscope 4 could also have the trigger enabled by test probe 8 or by test probe 6 in combination with test probe 8 depending upon particular test requirements. As best shown in FIG. 2, tip portion 70 is connected with an electrical circuit 100. At this point, pressure is applied to test probe 6 causing retractable probe tip 14 to shift into interior chamber portion 38. At the same time, a solid contact is established between tip portion 70 and electrical circuit 100. As pressure continues to be applied, retractable probe tip 14 overcomes the force applied by spring 75, pressure plate 66 disengages from stop switch 43 (opening the “stop” circuit and moves toward run switch 47. Once sufficient pressure is applied to test probe 6, pressure plate 66 connects with run switch 47 (closing the “run circuit” that enables oscilloscope 4 to trigger on the signal from electrical circuit 100 such as shown in FIG. 3. The signal is collected so long as sufficient pressure is applied to test probe 6. That is, in place of a panel mounted run switch to activate (enable, arm) oscilloscope 4, oscilloscope 4 is armed, once pressure plate 66 engages run switch 47 and oscilloscope 4 will have the trigger enabled and display a waveform if a trigger condition occurs.

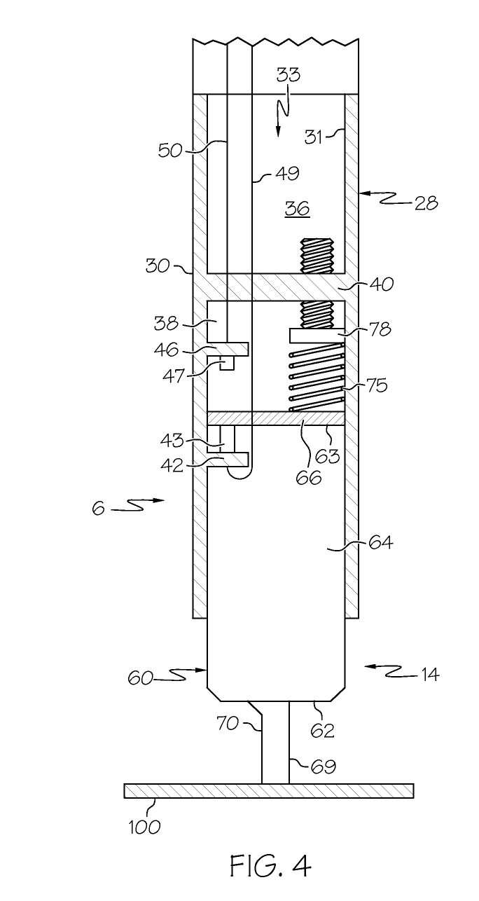

Once it is desired to cease collating the signal, pressure is removed from test probe 6 allowing spring 75 to urge pressure plate 66 away from wall member 40 breaking the connection in run switch 47 and engaging stop switch 43 such as shown in FIG. 4 and At this point it should be understood that the connection in stop switch 43 is closed while tip portion 70 remains in contact with electrical circuit 100. In this manner, no trigger will occur when stop contact 43 is engaged even if valid waveforms are present, thereby eliminating signal noise resulting from a poor connection between test probe 6 and circuit 100 while the probes are removed.

At this point it should be understood that exemplary embodiments of the present invention provide a system and method of enableing triggering on an oscilloscope through a test probe. The oscilloscopes trigger is on (activated armed or enabled) while the test probe remains in contact with an electrical circuit and switched off(disabled, disarmed, deactivated) before the probe is removed thereby eliminating unwanted signal noise when the probes are not making good contact. More over, exemplary embodiments of the present invention probe a test probe that can be operated by a single individual and which does not require any special use of fingers or the like to make a connection. That is, an individual missing one or more fingers can readily utilize the test probe of the present invention.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

1. A method of enabling triggering an oscilloscope comprising:
placing a run and stop switch in the tip portion of a probe being electrically connected to the oscilloscope and mechanically connected to the movement of the probe tip;
applying pressure to the probe tip; and
establishing a closure of the run switch as a result of pressure applied to the probe tip, the run switch closing a circuit that enables triggering the oscilloscope.

2. The method of claim 1, further comprising: shifting the probe tip into the probe to establish mechanical pressure to depress a run switch.

3. The method of claim 1, further comprising:
removing pressure from the probe tip;
establishing a closure of the stop switch as a result of reduced pressure applied to the probe tip, the stop switch closing a circuit that disables triggering the oscilloscope.

4. The method of claim 3, further comprising: extending the probe tip out from the probe to establish mechanical pressure to depress a stop switch.
